(19) United States
(12) Patent Application Publication
(10) Pub. No.: US 2026/0127332 A1
(43) Pub. Date: May 7, 2026

(54) MULTI-FACTOR BENEFIT ANALYSIS METHOD AND SYSTEM FOR RESILIENCE-ORIENTED POWER SYSTEM PLANNING SCHEME

(71) Applicant: XI'AN JIAOTONG UNIVERSITY, Xi'an (CN)

(72) Inventors: Zhaohong BIE, Xi'an (CN); Siyuan SUN, Xi'an (CN); Yiheng BIAN, Xi'an (CN); Zhengkun XIN, Xi'an (CN); Gengfeng LI, Xi'an (CN); Haipeng XIE, Xi'an (CN); Liyin ZHANG, Xi'an (CN); Qianwen HU, Xi'an (CN); Wei FU, Xi'an (CN); Bingkai HUANG, Xi'an (CN)

(73) Assignee: XI'AN JIAOTONG UNIVERSITY, Xi'an (CN)

(21) Appl. No.: 19/437,448

(22) Filed: Dec. 31, 2025

Related U.S. Application Data
(63) Continuation of application No. PCT/CN2025/104252, filed on Jun. 27, 2025.

(30) Foreign Application Priority Data
Sep. 10, 2024 (CN) 202411265084.1

(51) Int. Cl. G06F 30/18

(52) U.S. Cl. CPC G06F 30/18

(57) ABSTRACT

Disclosed is a multi-factor benefit analysis method and system for resilience-oriented power system planning schemes, including acquiring new power system planning schemes; evaluating the abilities of the acquired schemes to withstand extreme events within a set period of years, to obtain resilience indicators; estimating the acquired schemes by using the carbon emission flow method, to obtain carbon emission indicators; calculating the cost of constructing power facilities and the cost of reinforcing or renovating substations and lines, to obtain economic indicators; and evaluating and comparing the planning schemes under the evaluation and decision-making framework of new power system planning schemes for resilience enhancement by comprehensively considering the resilience indicators, carbon emission indicators, and economic indicators, to form a closed loop of decision-making, and give feedback to and correct the planning schemes, thereby achieving adaptive planning for the construction of new power systems under climate changes.

### CROSS-REFERENCE TO RELATED APPLICATIONS

The application claims priority to Chinese patent application No. 202411265084.1, filed on Sep. 10, 2024, the entire contents of which are incorporated herein by reference.

### TECHNICAL FIELD

The present application relates to the technical field of power system planning and technical and economic analysis, and specifically relates to a multi-factor benefit analysis method and system for resilience-oriented power system planning schemes.

### BACKGROUND

The power system is a national key core infrastructure concerning economic development, social stability, and national security. At present, China has the world's largest power system with the longest transmission lines, the highest voltage level, and the most complex grid structure. With the proposal of “carbon peaking and carbon neutrality” goals and the continuous advancement of new power system construction, power system security is facing new severe challenges under the influence of internal and external risks. First, the accelerated construction of a new power system will inevitably bring about major changes in the power supply structure, load characteristics, and grid morphology. Changes in essential characteristics of the system will lead to increased safety and stability risks. Second, global climate change is becoming more and more serious, and extreme weather and natural disasters, such as extreme cold, high temperatures, typhoons, and heavy rainfall, are showing a new normal of widespread, strong, frequent, and concurrent occurrences, making it much more difficult to ensure safe and reliable power supply. Third, the international situation is complex and changeable. Various types of man-made attacks such as strong electromagnetic pulses may become real threats to the power infrastructure during wartime, while China's power system still has shortcomings and a large gap with those of some other countries. Therefore, when we build a new power system, we shall take full consideration of improving the resilience of the system to extreme events with high impact and low probability, such as extreme natural disasters and man-made attacks, at the system planning stage, to ensure the safe and reliable power supply of the new power system from the source, which is of great significance for promoting the construction of the new power system.

At present, the study on the evaluation and decision-making for new power system planning schemes is not in-depth enough, and there is even a lack of decision-making on resilience-oriented planning schemes while taking into account normal operation and impact of extreme events. The conventional decisions on power system planning schemes are mainly made by economic and technical analysis under conventional operation scenarios. When we make a new power system planning scheme for resilience enhancement, we need to take into account both normal operation and impact of extreme events. Making reasonable decisions in planning scheme analysis is a key issue to be solved in the planning of the new power system for resilience enhancement. Therefore, it is necessary to develop new cost-benefit analysis and evaluation decision-making methods for resilience-oriented new power system planning schemes.

### SUMMARY

In view of the above-mentioned shortcomings in the prior art, this application provides a multi-factor benefit analysis method and system for resilience-oriented power system planning schemes, in which new power system planning schemes are evaluated by comprehensively considering multiple factors such as resilience indicators, carbon emission indicators, and economic indicators, to solve the technical problem that conventional robust or stochastic planning methods cannot simultaneously consider multiple complex scenarios involving resilience and carbon benefits, thereby providing a scientific decision-making basis for improving investment decision-making.

The technical solution adopted by the present application is as follows:
a multi-factor benefit analysis method for resilience-oriented power system planning schemes, including the following steps:
acquiring new power system planning schemes;
evaluating the ability of each of the acquired new power system planning schemes to withstand extreme events within a set period of years by extreme event simulation, component vulnerability analysis, system response behavior analysis, and resilience indicator calculation, to obtain resilience indicators;
estimating each of the acquired new power system planning schemes in terms of low-carbon costs of power system construction, at the source side, at the load side, and at the grid side during a planning period by using a carbon emission flow method, to obtain carbon emission indicators;
calculating the cost of constructing power facilities and the cost of reinforcing or renovating substations and lines, with respect to the implementation cost of each of the acquired new power system planning schemes, to obtain economic indicators; and
evaluating and comparing the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

Preferably, acquiring new power system planning schemes is specifically to acquire:
planning periods considered in the planning schemes;
planned capacities, integration locations, and years of manufacturing and commissioning of generator units of different types;
planned capacities, integration locations, and years of manufacturing and commissioning of energy storage systems of different types;
planned routes, line capacities, and years of construction and commissioning of power transmission line corridors;
planned locations and years of construction and commissioning of substations;
typical load data estimation during the planning years; and
typical daily operation modes of the power system during the planning years.

Preferably, evaluating each of the new power system planning schemes to obtain resilience indicators specifically includes:
for extreme event simulation, simulating the impact of the extreme events based on the characteristics thereof such as frequency, location, duration, and hazard intensity to generate a set of computer-simulated extreme event scenarios, and analyzing and calculating local hazard intensities at sites of interest for each simulated extreme event scenario; analyzing and selecting key parameters that characterize the extreme events based on historical disaster data, establishing probability distribution models or extreme value regression models for key parameters of the extreme events to describe the uncertainty of the extreme events, and performing hypothesis testing on the models to verify goodness of fit; and sampling the number of disaster occurrences for each simulation year during the planning period based on annual frequency distribution, sampling other key parameters for each disaster scenario to obtain initial states of simulated disasters, and converting the parameters into dynamic disaster scenarios with spatiotemporal characteristics by using meteorological or geographical models;
for component vulnerability analysis, based on disaster scenarios generated in extreme event simulation and vulnerability curves of power system components, calculating failure rates of power system components, and generating random numbers to sample the fault states of the components, to determine whether the power system components will fail in the corresponding disaster scenarios;
for system response behavior analysis, modeling the response process of the power system to extreme disasters, establishing an emergency control and restoration model for the power system against extreme events, and simulating the system power outage and restoration process; and
for resilience indicator calculation, defining risk loss as the weighted load loss and the maintenance cost of the system in an entire disaster, choosing the value at risk and the tail value at risk of loss as specific resilience indicators, using a Monte Carlo method to simulate economic loss caused each year, and achieving the convergence of the indicators by this year-by-year simulation during the planning period.

Preferably, the quantitative resilience indicator, the value at risk VaRₐ (X) and the tail value at risk TVaRₐ (X), are calculated as follows:

$$\begin{matrix}{VaR}_{α} ( X ) = inf \{ x : P ( X \leq x ) \geq α \} \\ {TVaR}_{α} ( X ) = \frac{1}{1 - α} {\int }_{α}^{1} {VaR}_{u} ( X ) du\end{matrix}$$

where inf{⋅} is the infimum, P(⋅) is the probability of an event, a is the set confidence level, X is the annual risk loss, and X is an auxiliary parameter for risk loss under a given confidence level α.

Preferably, the annual risk loss X is calculated as follows:

$$X = {\sum }_{r = 1}^{Λ} [ {\sum }_{k ∈ {F}_{r}^{L} ⋃ {F}_{r}^{N}} {L}_{k}^{repair} + X = {\sum }_{i ∈ N} {L}_{i}^{outage} ( {d}_{i , r} ) ]$$

where Λ is the total number of disasters in a simulation year,

$${F}_{r}^{L} and {F}_{r}^{N}$$

are the set of faulted lines and the set of faulted nodes in the r-th disaster respectively,

$${L}_{k}^{repair}$$

is the maintenance or reconstruction cost of the corresponding device of the component k,

$${L}_{i}^{outage}$$

is the economic loss of the lost load of the node i, and d_{i,r} is the duration of load loss of the nodei in the r-th disaster.

Preferably, estimating each of the new power system planning schemes to obtain carbon emission indicators specifically includes:
for each planning year during the planning period, determining the construction and commissioning conditions of generator units, energy storage systems, transmission lines, and substations in that year, and converting carbon emission levels of raw materials, production, and installation during the construction of power facilities;
characterizing direct carbon emissions of power generation at the source side by direct carbon emissions of different power plants at the source side of the power system under a typical daily operation mode, and converting the carbon emissions per unit of power generation of each unit based on the carbon emission factor of power generation;
characterizing indirect carbon emissions of power utilization at the load side by direct carbon emissions at the source side corresponding to customer power utilization behaviors under the typical daily operation mode, and converting the indirect carbon emissions per unit of power utilization of each customer corresponding to each node based on the carbon emission factor of the node;
characterizing indirect carbon emissions of grid loss at the grid side by accumulated carbon emissions coupled in power flows corresponding to the grid loss under the typical daily operation mode, and converting the accumulated carbon emissions based on carbon flow rate, including branch carbon flow rate and grid loss carbon flow rate, where the branch carbon flow rate is the indirect carbon emissions of the branches along with the power flow per unit of time, and the grid loss carbon flow rate represents the indirect carbon emissions of grid loss along with the power flow per unit of time;
summing carbon emissions of power facility construction, the direct carbon emissions of power generation at the source side, the indirect carbon emissions of power utilization at the load side, and the indirect carbon emissions of grid loss at the grid side of each year during the planning period, to obtain the carbon emission levels of the new power system planning schemes during the planning period; and
quantifying low-carbon costs, including a low-carbon investment cost and a low-carbon loss cost, where the low-carbon investment cost is estimated based on the initial investment in equipment and technology and the costs of related operating activities, and the low-carbon loss cost is the payment for carbon dioxide emissions.

Preferably, the low-carbon loss cost C^{CO}^{₂} is calculated as follows:

$${C}^{{CO}_{2}} = ( {E}^{power} - {D}^{G} ) \cdot {p}^{{CO}_{2}}$$

where D^{G} is the carbon emission quota, p^{CO}^{₂} is the price of carbon trading, and E^{power} is the carbon emissions generated by fuel consumption in the power system.

Preferably, calculating the cost of constructing power facilities and the cost of reinforcing or renovating substations and lines to obtain economic indicators specifically includes:
for power facility construction and allocation, calculating the costs of commissioning, operation, maintenance, decommissioning, and disposal of the power facilities during a planning period, where the power facilities include generator units, energy storage systems, transmission lines, and substations; and for the reinforcement, strengthening, upgrading, or construction standard improvement of substations and lines, calculating fixed investment costs and operation and maintenance costs.

Preferably, evaluating and comparing the planning schemes to form a closed loop of decision-making specifically includes:
analyzing impact of extreme events based on a study on evolution trends of the extreme events, to form the planning schemes;
evaluating each of the planning schemes in terms of the resilience indicators, the carbon emission indicators, and the economic indicators; and
comparing the planning schemes based on a given economic budget, choosing a Pareto optimal scheme for implementation, monitoring implemented strategies during system operation, and performing post-evaluation of effects, to form a closed loop of decision-making.

In a second aspect, the embodiments of the present application provide a multi-factor benefit analysis system for resilience-oriented power system planning schemes, including:
a planning module, configured to acquire new power system planning schemes;
a resilience module, configured to evaluate the ability of each of the acquired new power system planning schemes to withstand extreme events within a set period of years by extreme event simulation, component vulnerability analysis, system response behavior analysis, and resilience indicator calculation, to obtain resilience indicators;
a carbon emission module, configured to estimate each of the acquired new power system planning schemes in terms of low-carbon costs of power system construction, at the source side, at the load side, and at the grid side during a planning period by using a carbon emission flow method, to obtain carbon emission indicators;
an economic module, configured to calculate the cost of constructing power facilities and the cost of reinforcing or renovating substations and lines, with respect to the implementation cost of each of the acquired new power system planning schemes, to obtain economic indicators; and
an analysis module, configured to evaluate and compare the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

In a third aspect, the embodiments of the present application provide a computer device, which includes a memory, a processor, and a computer program stored in the memory and executable on the processor. When the processor executes the computer program, the steps of the multi-factor benefit analysis method for resilience-oriented power system planning schemes mentioned above are implemented.

In a fourth aspect, the embodiments of the present application provide a computer-readable storage medium, which includes a computer program. When the computer program is executed by the processor, the steps of the multi-factor benefit analysis method for resilience-oriented power system planning schemes mentioned above are implemented.

Compared with the prior art, the present application at least has the following beneficial effects:
The present application provides a multi-factor benefit analysis method for resilience-oriented power system planning schemes, which can quantitatively compare the advantages and disadvantages of different planning schemes, take into account conventional operation scenarios and extreme event scenarios, balance the economic efficiency and various benefit indicators, and provide a scientific reference basis for practical problems such as integration of renewable energy sources in the system, arrangement of expansion plans, optimization of operation modes, and improvement of investment decision-making.

Further, the present application establishes a complete process for evaluating the resilience benefits of the planning schemes considering the occurrence and development uncertainty of long-term extreme events, including extreme event simulation, component vulnerability analysis, system response behavior analysis, and resilience indicator calculation. For extreme event simulation, the method establishes probability distribution models or extreme value regression models for key parameters of extreme events to describe the uncertainty of characteristic parameters such as frequency, location, duration, and hazard intensity of extreme events in each simulation year. The parameters are converted into dynamic disaster scenarios with spatiotemporal characteristics by using meteorological or geographical models. This year-by-year simulation within the planning period realizes the convergence of the indicators to simulate the system's ability to withstand extreme events over a long period of time. For system response behavior analysis, the method takes into account emergency measures such as emergency control and restoration, which can accurately simulate the system response and restoration process. For indicator calculation, the method uses the value at risk and the tail value at risk of the annual loss as the quantitative indicators, performs year-by-year simulation within the planning period to realize the convergence of the indicators, and realizes the probabilistic evaluation of system disaster risks under the planning schemes.

Further, the present application establishes a process for evaluating the carbon emission benefits of the planning schemes, and gives the methods for estimating the carbon emissions at the source, grid, and load sides, to calculate the low-carbon investment costs and low-carbon loss costs, thereby realizing accurate and comprehensive calculation of the carbon emission benefits.

Further, the present application establishes an economic evaluation process for planning schemes, taking into account the cost of constructing power facilities such as generator units, energy storage systems, and transmission lines, as well as the cost of reinforcing or reconstructing substations and lines, which can comprehensively quantify the economic costs of the new power system planning schemes.

It is understood that the beneficial effects of the second aspect described above can be found in the relevant description of the first aspect mentioned above, and will not be repeated here.

In summary, the method of the present invention establishes a scientific and complete planning scheme evaluation method considering multiple factors such as resilience, carbon emissions, and economic efficiency, realizes the probabilistic evaluation of the resilience benefits taking into account the uncertainty of the occurrence and development of extreme events under long cycles and the system response and restoration process, and comprehensively quantifies carbon emissions at the source, grid, and load sides. This method can quantitatively compare the advantages and disadvantages of different planning schemes, take into account conventional operation scenarios and extreme event scenarios, balance the economic efficiency and various benefit indicators, and provide a scientific reference basis for practical problems such as integration of renewable energy sources in the system, arrangement of expansion plans, optimization of operation modes, and improvement of investment decision-making.

The technical solution of the present application is further described in detail below with reference to drawings and embodiments.

### BRIEF DESCRIPTION OF DRAWINGS

FIG. 1 is a flow chart of a resilience benefit analysis for a new power system planning scheme;

FIG. 2 is a visual illustration of simulating a disaster process of a typhoon;

FIG. 3 is a schematic diagram of sampling power system component faults under disaster scenarios;

FIG. 4 is a schematic diagram of an evaluation and decision-making framework of new power system planning schemes for resilience enhancement;

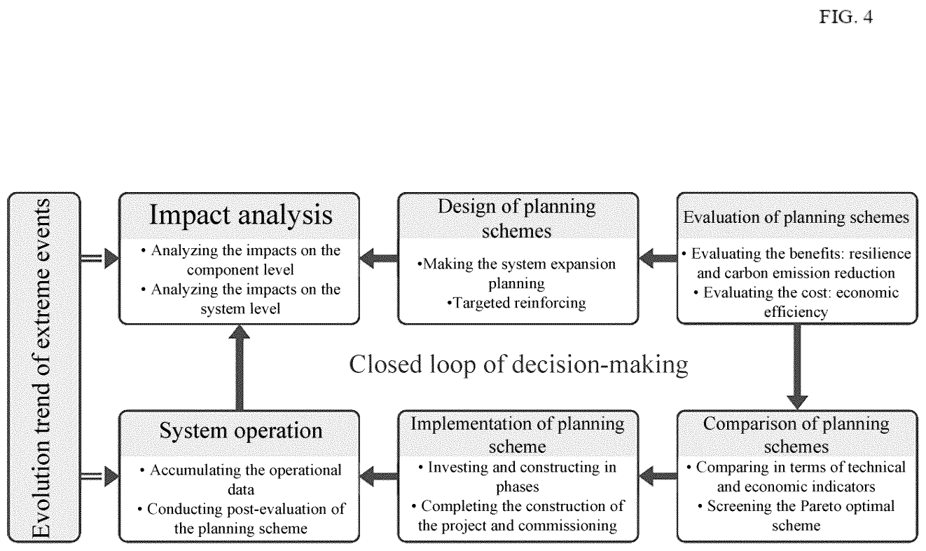

FIG. 5 is a schematic diagram of a computer device according to an embodiment of the present application; and

FIG. 6 is a block diagram of an electronic device according to an embodiment of the present application.

### DETAILED DESCRIPTION OF THE EMBODIMENTS

The present application provides a multi-factor benefit analysis method for resilience-oriented power system planning schemes, including the following steps:
S1: acquiring new power system planning schemes, which include determining planning periods considered in the planning schemes, construction and commissioning plans of generator units, energy storage systems, transmission lines, and substations in the planning schemes, typical load data estimation during the planning years, and typical daily operation modes during the planning years;
acquiring new power system planning schemes includes obtaining the following data:
S101: planning periods considered in the planning schemes;
S102: planned capacities, integration locations, and years of manufacturing and commissioning of generator units of different types, such as renewable energy generators and fuel-flexible thermal power generators;
S103: planned capacities, integration locations, and years of manufacturing and commissioning of energy storage systems of different types, such as pumped-storage hydroelectricity and batteries;
S104: planned routes, line capacities, and years of construction and commissioning of power transmission line corridors;
S105: planned locations and years of construction and commissioning of substations;
S106: typical load data estimation during the planning years; and
S107: typical daily operation modes of the power system during the planning years.
S2: evaluating the resilience enhancement effect of each of the planning schemes by extreme event simulation, component vulnerability analysis, system response behavior analysis, and resilience indicator calculation;
S201: simulating the impact of the extreme events based on the characteristics thereof such as frequency, location, duration, and hazard intensity to generate a set of a large number of computer-simulated extreme event scenarios, and analyzing and calculating local hazard intensities at sites of interest for each simulated extreme event scenario; analyzing and selecting key parameters (such as frequency, intensity, and duration) that can characterize the extreme events based on historical disaster data, establishing probability distribution models or extreme value regression models for key parameters of the extreme events to describe the uncertainty of the extreme events, and performing hypothesis testing on the models to verify goodness of fit; and sampling the number of disaster occurrences for each simulation year during the planning period based on annual frequency distribution, sampling other key parameters for each disaster scenario to obtain initial states of simulated disasters, and converting the parameters into dynamic disaster scenarios with spatiotemporal characteristics (such as typhoon tracks and heavy rainfall process) by using meteorological or geographical models.

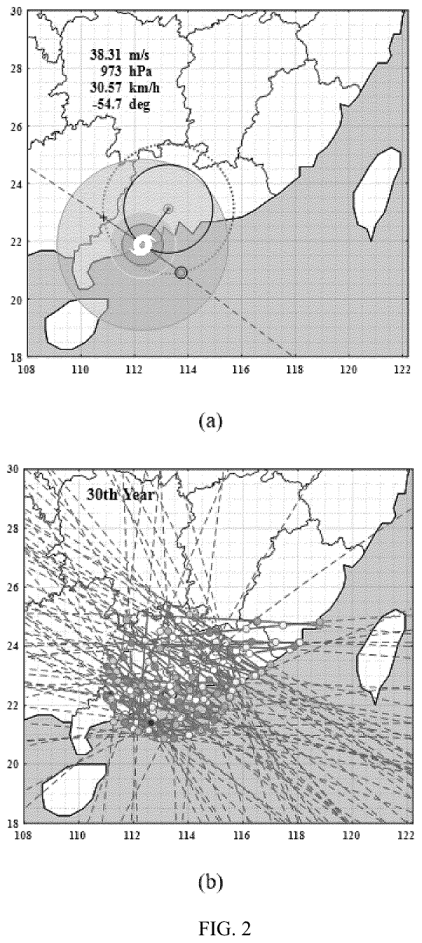

Taking typhoon disasters as an example, first, based on the Western North Pacific Tropical Cyclone Database, performing moment estimation, maximum likelihood estimation, and interval estimation on the parameters of the probability distributions of five key typhoon parameters, namely annual occurrence frequency, minimum distance, central pressure difference, translational velocity, and translational angle, and performing hypothesis testing on the probability models by the goodness-of-fit test method; and
then, based on the probability distribution models of the key parameters, as well as typhoon wind field models and filling models, building a simulated typhoon generator, which can generate typhoon track scenarios with specific hazard intensities according to certain probability distributions. Subsequent model examples are presented based on typhoon scenarios, as shown in FIG. 2.

S202: for component vulnerability analysis, based on disaster scenarios generated in extreme event analysis and vulnerability curves of power system components, calculating failure rates of power system components, and generating random numbers to sample the fault states of the components, to determine whether the power system components will fail in the corresponding disaster scenarios.

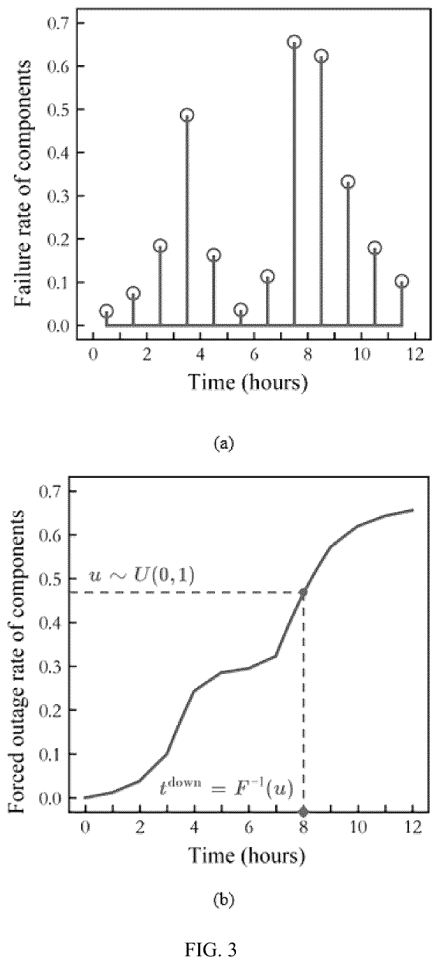

Taking the vulnerability analysis for power lines under typhoon disasters as an example, the availability function R(t) of the line during typhoon process is an exponential function with the failure rate λ(t) integrated over time as the exponent. What the simulated typhoon generator generates by sampling is hourly typhoon information data, so that it is assumed that the hourly failure rate of the line is a certain constant. Therefore, the availability function of the line during typhoon process is in the form of a piecewise exponential function. Based on the continuity of the availability curve, the availability function of the line during typhoon process can be written as:

$$R ( t ) = {C}_{k} {e}^{- {λ}_{k} ( t - {t}_{k} )} , {t}_{k} \leq t < {t}_{k + 1} \qquad ( 1 )$$

where the integral constant is determined by Cₖ=R(tₖ), and the forced outage rate function of the line during typhoon process is:

$$F ( t ) = 1 - {C}_{k} {e}^{- {λ}_{k} ( t - {t}_{k} )} , ∀ {t}_{k} \leq t < {t}_{k + 1} \qquad ( 2 )$$

where Cₖ=1−F(tₖ). FIG. 3 shows a schematic diagram of the curve of the forced outage rate function during typhoon process.

Determining the random outage time of the line in the typhoon track scenario according to the inverse function method. The specific method is as follows: randomly generating random numbers u˜U[0,1] uniformly distributed in the interval [0, 1], and the time t_{down} when u=F(t_{down}) as determined above is the random outage time of the line, as shown by the dotted line in FIG. 3. For each line, its random outage time during typhoon process can be determined by the method described above. If the obtained outage time of the line is later than the dissipation time of the typhoon, no outage will occur in this typhoon scenario.

S203: for system response behavior analysis, modeling the response process of the power system to extreme disasters, establishing an emergency control and restoration model for the power system against extreme events, and simulating the system power outage and restoration process, specifically including:
taking control measures such as fault identification, isolation, and load recovery when the disaster lasts, to reduce the impact of faults; and dispatching emergency repair personnel after the disaster to locate and clear faults and restore power supply rapidly.

Taking the response process of a new power distribution system under typhoon disasters as an example, the specific process is as follows:
(1) performing control operations with the power distribution automation system when the disaster lasts as on-site manual operations cannot be performed for safety concerns, including collecting the fault information of components through FTU and DTU and operating the states of remotely controlled switches;
(2) assigning line patrol or emergency repair tasks to the on-site operation and maintenance personnel after the disaster, for which line patrol tasks include going to fault areas for line patrol according to fault indications and confirming the status of the areas, and emergency repair tasks include repairing fault components and clearing faults;
(3) when it is confirmed that there is no fault in an area, the operation and maintenance personnel will restore the power supply of the area by using manual or remotely controlled switches and narrow the scope of the fault; and
(4) when all the fault components in a fault area are repaired, restoring the power supply of the area by operating remotely controlled or manual switches, and repeating this process till the system returns to normal power supply conditions.

S204: for resilience indicator calculation, defining risk loss as the weighted load loss and the maintenance cost of the system in an entire disaster; choosing the value at risk (VaR) and the tail value at risk (TVaR) of loss as specific resilience indicators; and using a Monte Carlo method to simulate the economic loss caused each year, and achieving the convergence of the indicators by this year-by-year simulation during the planning period.

The annual risk loss is calculated as follows:

$$X = {\sum }_{r - 1}^{Λ} [ X = {\sum }_{k ∈ {F}_{r}^{L} ⋃ {F}_{r}^{N}} {L}_{k}^{repair} + X = {\sum }_{i ∈ N} {L}_{i}^{outage} ( {d}_{i , r} ) ] \qquad ( 3 )$$

where Λ is the total number of typhoons in the simulation year,

$${F}_{r}^{L} and {F}_{r}^{N}$$

are the set of faulted lines and the set of faulted nodes in the r-th disaster respectively,

$${L}_{k}^{repair}$$

is the maintenance or reconstruction cost of the corresponding device of the component k,

$${L}_{i}^{outage}$$

is the economic loss of the lost load of the node i, and d_{i,r} is the duration of load loss of the nodei in the r-th typhoon.

After the annual risk loss is obtained, the quantitative resilience indicator VaR and TVaR are calculated as follows:

$${VaR}_{α} ( X ) = inf \{ x : P ( X \leq x ) \geq α \} \qquad ( 4 )$$

$${TVaR}_{α} ( X ) = \frac{1}{1 - α} {\int }_{α}^{1} {VaR}_{u} ( X ) du \qquad ( 5 )$$

where inf {⋅} is the infimum, P(⋅) is the probability of an event, and α is the set confidence level.

S3: for the carbon emission reduction benefits of each of the planning schemes, estimating the low-carbon costs of constructing the power system, at the source side, at the load side, and at the grid side during the planning period by using the carbon emission flow method;
S301: for each planning year during the planning period, determining the construction and commissioning conditions of generator units, energy storage systems, transmission lines, and substations in that year, and converting carbon emission levels of raw materials, production, and installation during the construction of power facilities;
S302: characterizing direct carbon emissions of power generation at the source side by direct carbon emissions of different power plants at the source side of the power system under a typical daily operation mode, and converting the carbon emissions per unit of power generation of each unit based on the carbon emission factor of power generation;
S303: characterizing indirect carbon emissions of power utilization at the load side by direct carbon emissions at the source side corresponding to customer power utilization behaviors under the typical daily operation mode, and converting the indirect carbon emissions per unit of power utilization of each customer corresponding to each node based on the carbon emission factor of the node;
S304: characterizing indirect carbon emissions of grid loss at the grid side by accumulated carbon emissions coupled in power flows corresponding to the grid loss under the typical daily operation mode, and converting the accumulated carbon emissions based on carbon flow rate, including branch carbon flow rate and grid loss carbon flow rate, where the branch carbon flow rate is the indirect carbon emissions of the branches along with the power flow per unit of time, and the grid loss carbon flow rate represents the indirect carbon emissions of grid loss along with the power flow per unit of time;
S305: summing carbon emissions of power facility construction, the direct carbon emissions of power generation at the source side, the indirect carbon emissions of power utilization at the load side, and the indirect carbon emissions of grid loss at the grid side of each year during the planning period, to obtain the carbon emission levels of the new power system planning schemes during the planning period; and
S306: quantifying low-carbon costs, including a low-carbon investment cost and a low-carbon loss cost, where the low-carbon investment cost can be estimated based on the initial investment in equipment and technology and the costs of related operating activities, and the low-carbon loss cost is the payment for carbon dioxide emissions.

The calculation method is as follows:

$${C}^{{CO}_{2}} = ( {E}^{power} - {D}^{G} ) \cdot {p}^{{CO}_{2}} \qquad ( 6 )$$

where C^{CO}^{₂} is the low-carbon loss cost, D^{G} is the carbon emission quota, and p^{CO}^{₂} the price of carbon trading.

S4: for the implementation costs of each of the planning schemes, calculating the cost of constructing power facilities such as generator units, energy storage systems, transmission lines, and substations, and the cost of reinforcing or renovating substations and lines;
S401: for the construction and allocation of power facilities such as generator units, energy storage systems, transmission lines, and substations, calculating the costs of their commissioning, operation, maintenance, decommissioning, and disposal during the planning period; and
S402: for the reinforcement, strengthening, upgrading, or construction standard improvement of substations and lines, calculating fixed investment costs and operation and maintenance costs.

S5: evaluating and comparing the planning schemes under an evaluation and decision-making framework of a new power system planning scheme for resilience enhancement by comprehensively considering the resilience indicators, the carbon emission indicators, and the economic indicators, to form a closed loop of decision-making.
S501: analyzing impact of the extreme events based on a study on evolution trends of the extreme events, to form the planning schemes;
S502: evaluating each of the planning schemes in terms of the resilience indicators, the carbon emission indicators, and the economic indicators according to Steps S1 to S4;
S503: comparing the planning schemes based on a given economic budget, choosing a Pareto optimal scheme for implementation, monitoring implemented strategies during system operation, and performing post-evaluation of effects, to form a closed loop of decision-making.

Those skilled in the art can understand that the various aspects of the present application can be implemented as systems, methods, or program products. Therefore, the various aspects of the present application may be specifically implemented in the following forms: an implementation completely with hardware, an implementation completely with software (including firmware and microcode), or an implementation combining both hardware and software, which can be generally referred to as “circuit”, “module”, or “platform”, respectively.

An embodiment of the present application provides a multi-factor benefit analysis system for resilience-oriented power system planning schemes, which can be used to achieve the multi-factor benefit analysis method for resilience-oriented power system planning schemes described above. Specifically, the multi-factor benefit analysis system for resilience-oriented power system planning schemes includes:
a planning module, configured to acquire new power system planning schemes;
a resilience module, configured to evaluate the ability of each of the acquired new power system planning schemes to withstand extreme events within a set period of years by extreme event simulation, component vulnerability analysis, system response behavior analysis, and resilience indicator calculation, to obtain resilience indicators;
a carbon emission module, configured to estimate each of the acquired new power system planning schemes in terms of low-carbon costs of power system construction, at the source side, at the load side, and at the grid side during a planning period by using a carbon emission flow method, to obtain carbon emission indicators;
an economic module, configured to calculate the cost of constructing power facilities and the cost of reinforcing or renovating substations and lines, with respect to the implementation cost of each of the acquired new power system planning schemes, to obtain economic indicators; and
an analysis module, configured to evaluate and compare the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

Another embodiment of the present application provides a terminal device, which includes a processor and a memory; the memory is configured to store a computer program; the computer program includes program instructions; and the processor is configured to execute the program instructions stored in the computer storage medium. The processor may be a central processing unit (CPU), any other general-purpose processor, digital signal processor (DSP), application specific integrated circuit (ASIC), field-programmable gate array (FPGA), any other programmable logic device, discrete gate, transistor logic device, or discrete hardware component; it is the computing core and control core of the terminal, and is suitable for implementing one or more instructions, specifically suitable for loading and executing one or more instructions to implement corresponding method flows or functions. The processor according to the embodiments of the present application can be used for the operations of the multi-factor benefit analysis method for resilience-oriented power system planning schemes, including:
acquiring new power system planning schemes; evaluating the ability of each of the acquired new power system planning schemes to withstand extreme events within a set period of years by extreme event simulation, component vulnerability analysis, system response behavior analysis, and resilience indicator calculation, to obtain resilience indicators; estimating each of the acquired new power system planning schemes in terms of low-carbon costs of power system construction, at the source side, at the load side, and at the grid side during a planning period by using a carbon emission flow method, to obtain carbon emission indicators; calculating the cost of constructing power facilities and the cost of reinforcing or renovating substations and lines, with respect to the implementation cost of each of the acquired new power system planning schemes, to obtain economic indicators; and evaluating and comparing the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

Another embodiment of the present application further provides a storage medium, specifically a computer-readable storage medium (memory), which is the memory device of the terminal device for storing programs and data. It can be understood that the computer-readable storage medium mentioned here may include both a built-in storage medium in the terminal device and an extended storage medium supported by the terminal device, and may be any tangible medium containing or storing a program that can be used by or in combination with an instruction execution system, device, or apparatus. The computer-readable storage medium provides a storage space that stores the operating system of the terminal. In addition, one or more instructions suitable for being loaded and executed by the processor are also stored in the storage space. These instructions may be one or more computer programs (including program code). It should be noted that more specific examples (a non-exhaustive list) of the computer-readable storage medium mentioned here include an electrical connection with one or more wires, a portable disk, a hard disk, a random access memory (RAM), a read-only memory (ROM), an erasable programmable read-only memory (EPROM or flash memory), an optical fiber, a portable compact disk read-only memory (CD-ROM), an optical storage device, a magnetic storage device, or any suitable combination of the above.

The computer-readable storage medium further includes data signals propagated in the baseband or as part of the carrier wave, which carries readable program code. These propagated data signals can be in a variety of forms, including but not limited to electromagnetic signals, optical signals, or any suitable combination of the above. The readable storage medium may also be any readable medium other than a readable storage medium that can send, transmit, or transfer programs for use by or in combination with instruction execution systems, devices, or apparatuses. The program code contained on the readable storage medium may be transmitted using any suitable medium, including but not limited to wireless networks, wired networks, optical cable, RF, or any suitable combination of the above.

The program code for performing the operations of the present application may be written in any combination of one or more programming languages, including object-oriented programming languages such as Java and C++, and conventional procedural programming languages such as C language. The program code may be executed entirely on a user's computing device, partially on the user's device, as a stand-alone software package, partially on the user's computing device and partially on a remote computing device, or entirely on a remote computing device or server. In cases involving remote computing devices, the remote computing device may be connected with a user's computing device through any kind of network including a local area network (LAN) or a wide area network (WAN), or with an external computing device (for example, via the Internet using an Internet service provider).

The processor can load and execute one or more instructions stored in the computer-readable storage medium to implement the corresponding steps of the multi-factor benefit analysis method for resilience-oriented power system planning schemes in the above embodiment; and the one or more instructions in the computer-readable storage medium are loaded and executed by the processor as follows:
acquiring new power system planning schemes; evaluating the ability of each of the acquired new power system planning schemes to withstand extreme events within a set period of years by extreme event simulation, component vulnerability analysis, system response behavior analysis, and resilience indicator calculation, to obtain resilience indicators; estimating each of the acquired new power system planning schemes in terms of low-carbon costs of power system construction, at the source side, at the load side, and at the grid side during a planning period by using a carbon emission flow method, to obtain carbon emission indicators; calculating the cost of constructing power facilities and the cost of reinforcing or renovating substations and lines, with respect to the implementation cost of each of the acquired new power system planning schemes, to obtain economic indicators; and evaluating and comparing the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

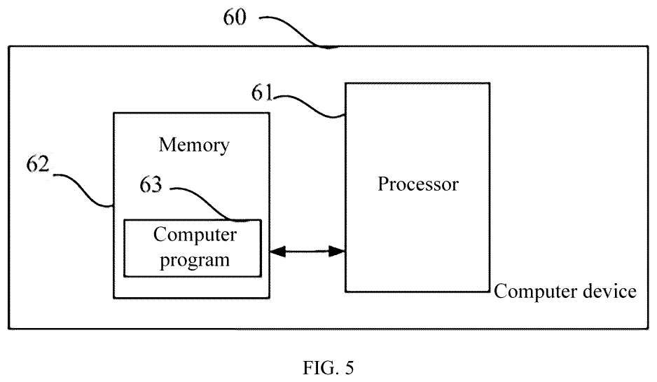

Referring to FIG. 5, the terminal device is a computer device. The computer device 60 of this embodiment includes a processor 61, a memory 62, and a computer program 63 stored in the memory 62 and executable on the processor 61. When the processor 61 executes the computer program 63, the multi-factor benefit analysis method for resilience-oriented power system planning schemes in the embodiment can be implemented. To avoid repetition, this content will not be repeated here. Alternatively, when the computer program 63 is executed by the processor 61, the functions of each model/unit in the multi-factor benefit analysis system for resilience-oriented power system planning schemes in the embodiment can be implemented. To avoid repetition, this content will not be repeated here.

The computer device 60 may be a computing device such as a desktop computer, a notebook, a PDA, or a cloud server. The computer device 60 may include, but is not limited to, a processor 61 and a memory 62. Those skilled in the art can understand that FIG. 5 is only an example of the computer device 60 and does not constitute a limitation on the computer device 60. The computer device 60 may include more or fewer components than those shown, or combine some or different components. For example, the computer device can further include components such as input and output devices, network access devices, and buses.

The processor 61 may be a central processing unit (CPU), any other general-purpose processor, graphics processor, digital signal processor (DSP), application specific integrated circuit (ASIC), field-programmable gate array (FPGA), any other programmable logic device, discrete gate, or transistor logic device, data processing logic based on quantum computing, or discrete hardware component. The general-purpose processor may be a microprocessor or any conventional processor.

The memory 62 may be an internal storage unit of the computer device 60, such as a hard disk or memory of the computer device 60. The memory 62 may further be an external storage device of the computer device 60, such as a plug-in hard disk, a smart media card (SMC), a secure digital (SD) card, or a flash card (Flash Card) equipped on the computer device 60.

Further, the memory 62 may further include both an internal storage unit of the computer device 60 and an external storage device. The memory 62 is configured to store computer programs and other programs and data needed by the computer device. The memory 62 may further be configured to temporarily store data that has been output or is about to be output.

In the embodiments provided in the present application, any reference to memory, databases, or other media may include at least one of non-volatile and volatile memory. The non-volatile memory may include a read-only memory (ROM), magnetic tape, floppy disk, flash memory, optical storage, high-density embedded non-volatile memory, resistive random access memory (ReRAM), magnetoresistive random access memory (MRAM), ferroelectric random access memory (FRAM), phase change memory (PCM), graphene memory, and so forth. The volatile memory may include random access memory (RAM) or external cache memory. For illustrative rather than limiting purposes, the RAM may be in various forms, such as static random access memory (SRAM) or dynamic random access memory (DRAM).

The databases involved in the embodiments provided by the present application may include at least one of a relational database and a non-relational database. The non-relational database may include blockchain-based distributed databases, and so forth, without limitation. The processor involved in the embodiments provided by the present application may include, but is not limited to, a general-purpose processor, a central processing unit, a graphics processor, a digital signal processor, a programmable logic device, and a quantum computing-based data processing logic device.

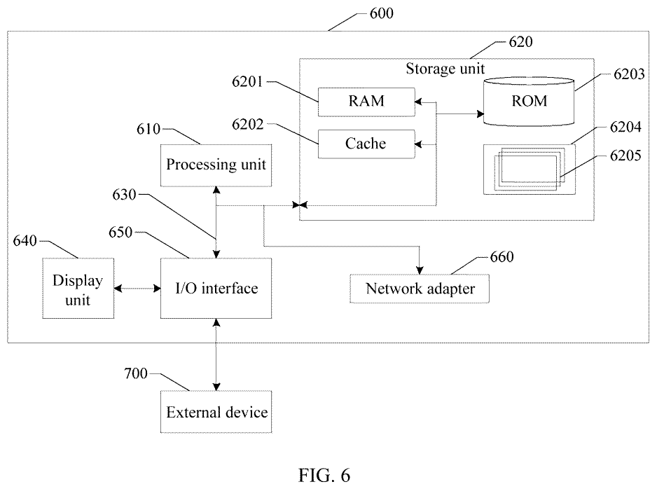

Referring to FIG. 6, the terminal device 600 is an electronic device in the form of a general-purpose computing device. The components of the electronic device may include but are not limited to at least one processing unit 610, at least one storage unit 620, a bus 630 connecting different platform components (including the storage unit 620 and the processing unit 610), and a display unit 640.

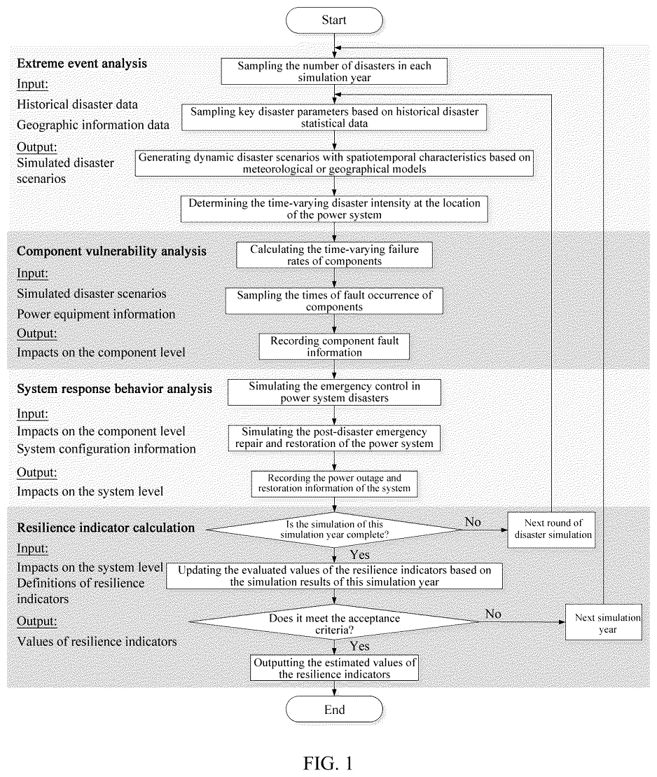

Among these components, the storage unit stores the program code that can be executed by the processing unit 610, so that the processing unit 610 performs the steps according to the exemplary embodiments of the present application described in the method section of this specification. For example, the processing unit 610 can perform the steps shown in FIG. 1.

The storage unit 620 may include a readable medium in the form of a volatile storage unit, such as a random access memory (RAM) 6201 and/or a cache memory 6202, and may further include a read-only memory (ROM) 6203.

The storage unit 620 may further include a program/utility 6204 that has a set (at least one) of program modules 6205, including but not limited to an operating system, one or more applications, other program modules, and program data, and each or some combination of these examples may include implementations of a network environment.

The bus 630 may be one or more of several types of bus structures, including the bus or controller of the storage unit, peripheral bus, accelerated graphics port, processing unit, or local bus using any one of the bus structures.

The electronic device 600 may further communicate with one or more external devices 700 (such as a keyboard, a pointing device, and a Bluetooth device), with one or more devices that enable a user to interact with the electronic device 600, and/or with any device (such as a router and a modem) that enables the electronic device 600 to communicate with one or more other computing devices. Such communication may be implemented through an input/output (I/O) interface 650. In addition, the electronic device 600 may also communicate with one or more networks (such as a local area network (LAN), a wide area network (WAN), and/or a public network (such as the Internet)) through a network adapter 660. The network adapter 660 can communicate with other modules of the electronic device 600 via the bus 630. It should be understood that although not shown in the drawings, other hardware and/or software modules may be used in conjunction with the electronic device 600, including but not limited to microcode, device drivers, redundant processing units, external disk drive arrays, RAID systems, tape drives, and data backup storage platforms.

To make the purpose, technical solutions, and advantages of embodiments of the present disclosure clearer, the technical solutions in embodiments of the present disclosure will be explicitly and completely described below with reference to the accompanying drawings in embodiments of the present disclosure. Obviously, embodiments described are only some, not all, of the embodiments of the present disclosure. The components of embodiments of the present application generally described and illustrated in the drawings herein may be arranged and designed in a variety of different configurations. Accordingly, the following detailed description of embodiments of the present disclosure provided in the accompanying drawings is not intended to limit the scope of the claimed present disclosure but merely represents selected embodiments of the present disclosure. Based on the embodiments described herein, all other embodiments obtained by those of ordinary skill in the art without creative work are within the scope of protection of the present disclosure.

To simulate the multi-factor benefit analysis method for resilience-oriented power system planning schemes provided by the present application, a simulation environment is designed to use computer software and algorithms to simulate the performance of different planning schemes in terms of extreme events, component vulnerability, system response, carbon emissions, and economic efficiency. The following is an example of a simplified simulation process:

### 1. Initialization and Data Preparation

Defining system parameters, including the basic structure of the power system (such as grid topology, types and locations of power plants, and load points), and equipment parameters (such as generator capacities, and transmission line capacities and impedances).

Preparing planning scheme input: preparing multiple new power system planning schemes, including different power supply configurations, expansion plans, and energy storage allocation schemes.

### 2. Extreme Event Simulation

Simulating the impact of extreme events: simulating the impact of extreme events based on the characteristics of extreme events such as frequency, location, duration, and hazard intensity to generate a set of a large number of computer-simulated extreme event scenarios, and analyzing and calculating local hazard intensities at sites of interest for each simulated extreme event scenario.

### 3. Component Vulnerability Analysis and System Response

Vulnerability analysis: evaluating the failure probability and consequence severity of each component under extreme events based on historical data and expert knowledge.

System response simulation: simulating the remote control and on-site repair response measures of the system after extreme events (such as remote topology reconfiguration, manual switch operations, and fault repair), and recording the system recovery process.

### 4. Resilience Indicator Calculation

Defining the resilience indicators: defining the risk loss as the weighted load loss and the maintenance cost of the system in an entire disaster, and choosing the value at risk and the tail value at risk of loss as the specific resilience indicators.

Calculating the resilience indicators: using the Monte Carlo method to simulate the economic loss caused each year, and achieving the convergence of the indicators by this year-by-year simulation during the planning period.

### 5. Carbon Emissions and Low-Carbon Cost Estimation

Building the carbon emission flow model: building a carbon emission model for the entire life cycle of the power system, including the carbon emissions in the construction phase, operation phase, and decommissioning phase.

Estimating the low-carbon cost: estimating the low-carbon cost of each of the planning schemes based on the carbon emission flow model according to the carbon emission rights trading price or the carbon tax policies.

### 6. Economic Evaluation

Calculating the cost: including the cost of constructing power facilities, the cost of reinforcing or reconstructing substations and lines, and the operation and maintenance cost.

Calculating the economic indicators: including the total cost, investment payback period, and net present value of each of the planning schemes.

### 7. Comprehensive Evaluation and Decision-Making

Building an evaluation framework: building an evaluation and decision-making framework of new power system planning schemes for resilience enhancement by considering the resilience indicators, carbon emission indicators, and economic indicators.

Comparing the schemes: comprehensively evaluating and comparing the planning schemes by using the Pareto multi-objective optimization method.

Providing feedback and correcting: providing feedback and correcting the planning schemes according to the evaluation results, to optimize the scheme design.

### 8. Result Output and Visualization

Generating an evaluation report: organizing the simulation results and generating a detailed evaluation report, including the comparison chart and comprehensive evaluation ranking of the planning schemes in terms of the resilience indicators, the carbon emission indicators, and the economic indicators.

Visually illustrating: using charts, maps, and other forms to intuitively illustrate the key information of the planning schemes, such as their performances under extreme events, carbon emission distributions, and economic costs.

By using the simulation procedure described above, the comprehensive benefits of different new power system planning schemes in terms of resilience, carbon emissions and economic efficiency can be systematically evaluated to provide a scientific basis for decision makers.

In summary, the present application provides a multi-factor benefit analysis method and system for resilience-oriented power system planning schemes, which can evaluate new power system planning schemes by integrating three types of indicators, namely resilience, carbon emissions, and economic efficiency, and provide scientific reference basis for practical problems such as integration of renewable energy sources in the system, arrangement of the expansion planning, optimization of the operation mode, and improvement of investment decision-making.

The above content is only to illustrate the technical idea of the present disclosure, and cannot limit the scope of protection of the present disclosure. Any changes made on the basis of the technical solution in accordance with the technical idea proposed by the present disclosure shall fall within the scope of protection of the claims of the present disclosure.

What is claimed is:

1. A multi-factor benefit analysis method for resilience-oriented power system planning schemes, comprising the following steps:
acquiring new power system planning schemes;
evaluating the ability of each of the acquired new power system planning schemes to withstand extreme events within a set period of years by extreme event simulation, component vulnerability analysis, system response behavior analysis, and resilience indicator calculation, to obtain resilience indicators;
estimating each of the acquired new power system planning schemes in terms of low-carbon costs of power system construction, at the source side, at the load side, and at the grid side during a planning period by using a carbon emission flow method, to obtain carbon emission indicators;
calculating the cost of constructing power facilities and the cost of reinforcing or renovating substations and lines, with respect to the implementation cost of each of the acquired new power system planning schemes, to obtain economic indicators; and
evaluating and comparing the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.

2. The multi-factor benefit analysis method for resilience-oriented power system planning scheme according to claim 1, wherein acquiring new power system planning schemes is specifically to acquire:
planning periods considered in the planning schemes;
planned capacities, integration locations, and years of manufacturing and commissioning of generator units of different types;
planned capacities, integration locations, and years of manufacturing and commissioning of energy storage systems of different types;
planned routes, line capacities, and years of construction and commissioning of power transmission line corridors;
planned locations and years of construction and commissioning of substations;
typical load data estimation during the planning years; and
typical daily operation modes of the power system during the planning years.

3. The multi-factor benefit analysis method for resilience-oriented power system planning schemes according to claim 1, wherein evaluating each of the new power system planning schemes to obtain resilience indicators specifically comprises:
for extreme event simulation, simulating the impact of the extreme events based on the characteristics thereof such as frequency, location, duration, and hazard intensity to generate a set of computer-simulated extreme event scenarios, and analyzing and calculating hazard intensities at sites of interest for each simulated extreme event scenario; analyzing and selecting key parameters that characterize the extreme events based on historical disaster data, establishing probability distribution models or extreme value regression models for key parameters of the extreme events to describe the uncertainty of the extreme events, and performing hypothesis testing on the models to verify goodness of fit; and sampling the number of disaster occurrences for each simulation year during the planning period based on annual frequency distribution, sampling other key parameters for each disaster scenario to obtain initial states of simulated disasters, and converting the parameters into dynamic disaster scenarios with spatiotemporal characteristics by using meteorological or geographical models;
for component vulnerability analysis, based on disaster scenarios generated in extreme event analysis and vulnerability curves of power system components, calculating failure rates of power system components, and generating random numbers to sample the fault states of the components, to determine whether the power system components will fail in the corresponding disaster scenarios;
for system response behavior analysis, modeling the response process of the power system to extreme disasters, establishing an emergency control and restoration model for the power system to respond to extreme events, and simulating the system power outage and restoration process; and
for resilience indicator calculation, defining risk loss as the weighted load loss and the maintenance cost of the system in an entire disaster, choosing the value at risk and the tail value at risk of loss as specific resilience indicators, using a Monte Carlo method to simulate economic loss caused each year, and achieving the convergence of the indicators by this year-by-year simulation during the planning period.

4. The multi-factor benefit analysis method for resilience-oriented power system planning schemes according to claim 3, wherein the quantitative resilience indicator VaRₐ (X) and the tail value at risk TVaRₐ (X) are calculated as follows:
$$\begin{matrix}{VaR}_{α} ( X ) = inf \{ x : P ( X \leq x ) \geq α \} \\ {TVaR}_{α} ( X ) = \frac{1}{1 - α} {\int }_{α}^{1} {VaR}_{u} ( X ) du\end{matrix}$$
where inf{⋅} is the infimum, P(⋅) is the probability of an event, α is the set confidence level, X is the annual risk loss, and X is an auxiliary parameter for risk loss under a given confidence level α.

5. The multi-factor benefit analysis method for resilience-oriented power system planning schemes according to claim 4, wherein the annual risk loss X is calculated as follows:
$$X = {\sum }_{r - 1}^{Λ} [ X = {\sum }_{k ∈ {F}_{r}^{L} ⋃ {F}_{r}^{N}} {L}_{k}^{repair} + X = {\sum }_{i ∈ N} {L}_{i}^{outage} ( {d}_{i , r} ) ]$$
where Λ is the total number of disasters in the simulation year,
$${F}_{r}^{L} and {F}_{r}^{N}$$
are the set or lines in fault and the set of nodes in fault in the r-th disaster respectively,
$${L}_{k}^{repair}$$
is the maintenance or reconstruction cost of the corresponding device of the component k,
$${L}_{i}^{outage}$$
is the economic loss of the lost load of the node i, and d_{i,r} is the duration of load loss of the nodei in the r-th disaster.

6. The multi-factor benefit analysis method for resilience-oriented power system planning schemes according to claim 1, wherein estimating each of the new power system planning schemes to obtain carbon emission indicators specifically comprises:
for each planning year during the planning period, determining the construction and commissioning conditions of generator units, energy storage systems, transmission lines, and substations in that year, and converting carbon emission levels of raw materials, production, and installation during the construction of power facilities;
characterizing direct carbon emissions of power generation at the source side by direct carbon emissions of different power plants at the source side of the power system under a typical daily operation mode, and converting the carbon emissions per unit of power generation of each unit based on the carbon emission factor of power generation;
characterizing indirect carbon emissions of power utilization at the load side by direct carbon emissions at the source side corresponding to customer power utilization behaviors under the typical daily operation mode, and converting the indirect carbon emissions per unit of power utilization of each customer corresponding to each node based on the carbon emission factor of the node;
characterizing indirect carbon emissions of grid loss at the grid side by accumulated carbon emissions coupled in power flows corresponding to the grid loss under the typical daily operation mode, and converting the accumulated carbon emissions based on carbon flow rate, including branch carbon flow rate and grid loss carbon flow rate, wherein the branch carbon flow rate is the indirect carbon emissions of the branches along with the power flow per unit of time, and the grid loss carbon flow rate represents the indirect carbon emissions of grid loss along with the power flow per unit of time;
summing carbon emissions of power facility construction, the direct carbon emissions of power generation at the source side, the indirect carbon emissions of power utilization at the load side, and the indirect carbon emissions of grid loss at the grid side of each year during the planning period, to obtain the carbon emission levels of the new power system planning schemes during the planning period; and
quantifying low-carbon costs, including a low-carbon investment cost and a low-carbon loss cost, wherein the low-carbon investment cost is estimated based on the initial investment in equipment and technology and the costs of related operating activities, and the low-carbon loss cost is the payment for carbon dioxide emissions.

7. The multi-factor benefit analysis method for resilience-oriented power system planning schemes according to claim 6, wherein the low-carbon loss cost C^{CO}^{₂} is calculated as follows:
$${C}^{{CO}_{2}} = ( {E}^{power} - {D}^{G} ) \cdot {p}^{{CO}_{2}}$$
where D^{G} is the carbon emission quota, p^{CO}^{₂} is the price of carbon trading, and E^{power} is the carbon emissions generated by fuel consumption in the power system.

8. The multi-factor benefit analysis method for resilience-oriented power system planning schemes according to claim 1, wherein calculating the cost of constructing power facilities and the cost of reinforcing or renovating substations and lines to obtain economic indicators specifically comprises:
for power facility construction and allocation, calculating the costs of commissioning, operation, maintenance, decommissioning, and disposal of the power facilities during a planning period, wherein the power facilities comprise generator units, energy storage systems, transmission lines, and substations; and for the reinforcement, strengthening, upgrading, or construction standard improvement of substations and lines, calculating fixed investment costs and operation and maintenance costs.

9. The multi-factor benefit analysis method for resilience-oriented power system planning schemes according to claim 1, wherein evaluating and comparing the planning schemes to form a closed loop of decision-making specifically comprises:
analyzing impact of the extreme events based on a study on evolution trends of the extreme events, to form the planning schemes;
evaluating each of the planning schemes in terms of the resilience indicators, the carbon emission indicators, and the economic indicators; and
comparing the planning schemes based on a given economic budget, choosing a Pareto optimal scheme for implementation, monitoring implemented strategies during system operation, and performing post-evaluation of effects, to form a closed loop of decision-making.

10. A multi-factor benefit analysis system for resilience-oriented power system planning schemes, comprising:
a planning module, configured to acquire new power system planning schemes;
a resilience module, configured to evaluate the ability of each of the acquired new power system planning schemes to withstand extreme events within a set period of years by extreme event simulation, component vulnerability analysis, system response behavior analysis, and resilience indicator calculation, to obtain resilience indicators;
a carbon emission module, configured to estimate each of the acquired new power system planning schemes in terms of low-carbon costs of power system construction, at the source side, at the load side, and at the grid side during a planning period by using a carbon emission flow method, to obtain carbon emission indicators;
an economic module, configured to calculate the cost of constructing power facilities and the cost of reinforcing or renovating substations and lines, with respect to the implementation cost of each of the acquired new power system planning schemes, to obtain economic indicators; and
an analysis module, configured to evaluate and compare the planning schemes under an evaluation and decision-making framework of new power system planning schemes for resilience enhancement by comprehensively considering the resilience indicators, the carbon emission indicators, and the economic indicators, to form a closed loop of decision-making, and give feedback to and correct the planning schemes, thereby achieving adaptive planning for new power system construction under climate changes.
